(19) United States
(12) Patent Application Publication
(10) Pub. No.: US 2008/0122016 A1
(43) Pub. Date: May 29, 2008

(54) Semiconductor device and fabricating method thereof

(75) Inventor: Yong ho Oh, Bupyeong-gu (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/981,322

(22) Filed: Oct. 30, 2007

(30) Foreign Application Priority Data
Nov. 27, 2006 (KR) 10-2006-0117461

(51) Int. Cl. H01L 29/78; H01L 21/336

(52) U.S. Cl. 257/407; 438/303; 257/E29.255; 257/E21.437

(57) ABSTRACT

A semiconductor device includes: a semiconductor substrate including source/drain regions and a channel between the source/drain regions; a gate oxide layer pattern on the channel; a metal nitride layer pattern on the gate oxide layer pattern; a silicide on the metal nitride layer pattern; and a spacer on a side of the gate oxide layer pattern, the metal nitride layer pattern, and the silicide. In one embodiment, the metal nitride layer pattern is ¼ to ½ as thick as the silicide.

### CROSS-REFERENCE TO RELATED APPLICATIONS

The present application claims priority under 35 U.S.C. 119 and 35 U.S.C. 365 to Korean Patent Application No. 10-2006-0117461 (filed on Nov. 27, 2006), which is hereby incorporated by reference in its entirety.

### BACKGROUND

Most complementary metal oxide semiconductor (CMOS) devices include gates formed of polysilicon. If the gates are formed of polysilicon, depletion layers are inevitably formed regardless of their size. When the degree of integration of semiconductor devices is not high, relatively large poly gates may be formed. Therefore, even though depletion layers are formed, degradation of electrical properties can be negligible.

However, as semiconductor devices are highly integrated, the size of gates is further reduced, and thus the influence of depletion layers formed in the gates is relatively great. The depletion layers are one factor that degrades the performance of semiconductor devices. That is, the depletion layers are considered as an important issue in semiconductor devices using polysilicon. A metal gate has been proposed as one approach to preventing degradation of the performance of the semiconductor devices by the depletion layers.

However, when the metal gate is formed, it is generally difficult to perform metal etching. Therefore, instead of a gate-first process (i.e., first directly forming a gate electrode by photolithography), a replacement gate process may be carried out in which a gate region is defined in a trench in a sacrificial layer, and the trench with a metal. However, the replacement gate process may have misalignment issues.

### SUMMARY

Embodiments of the present invention provide a semiconductor device, which can prevent or reduce possible malfunctions caused by a depletion layer resulting from the use of a polysilicon electrode, and a fabricating method thereof.

In one embodiment, a semiconductor device includes: a semiconductor substrate including source/drain regions and a channel between the source/drain regions; a gate oxide layer pattern on the channel; a metal nitride layer pattern on the gate oxide layer pattern; a silicide on the metal nitride layer pattern; and a spacer on sides of the gate oxide layer pattern, the metal nitride layer pattern, and the silicide. The metal nitride layer pattern is ¼ to ½ (e.g., ⅓ to ½) of the thickness of the silicide.

The details of one or more embodiments are set forth in the accompanying drawings and the description below. Other features will be apparent from the description and drawings, and from the claims.

### BRIEF DESCRIPTION OF THE DRAWINGS

FIGS. 1 to 4 are cross-sectional views illustrating a method for fabricating a semiconductor device according to an embodiment.

FIG. 5 is a cross-sectional view of a semiconductor device according to an embodiment.

### DETAILED DESCRIPTION OF THE EMBODIMENTS

Reference will now be made in detail to the embodiments of the present disclosure, examples of which are illustrated in the accompanying drawings.

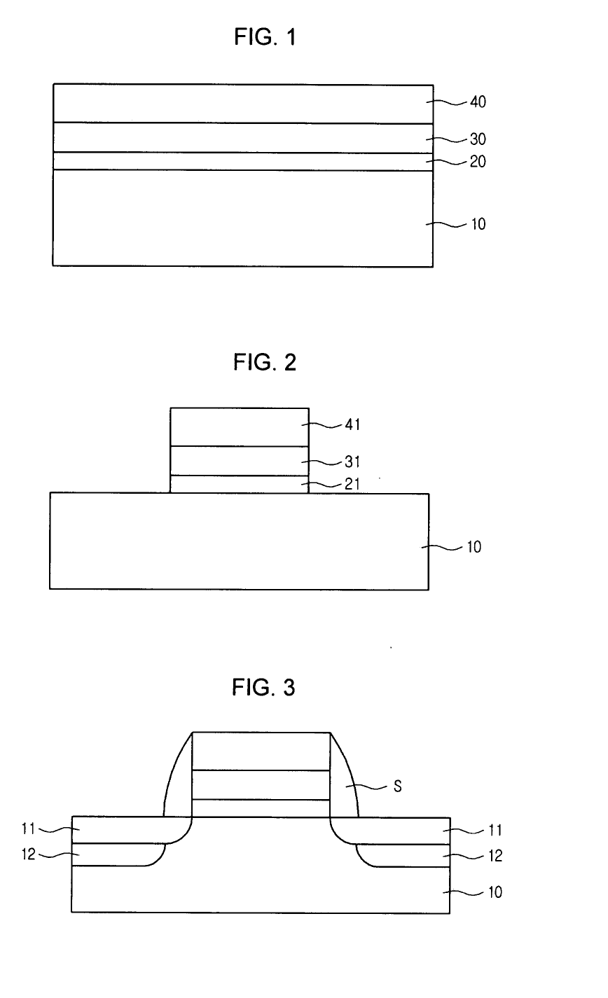

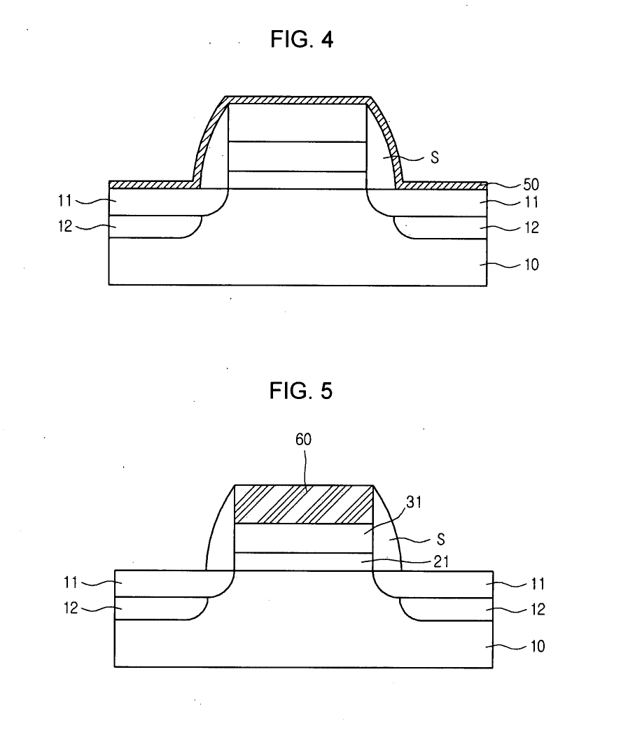

FIGS. 1 to 4 are cross-sectional views illustrating a method for fabricating a semiconductor device according to embodiments of the invention, and FIG. 5 is a cross-sectional view of a semiconductor device according to an embodiment of the invention.

Referring to FIG. 1, a gate oxide layer 20 is grown or deposited on a semiconductor substrate 10 by a known method. Gate oxide layer 20 may comprise thermally grown silicon dioxide or a high k oxide such as silicon oxynitride, silicon nitride, hafnium dioxide, etc., which can be thermally grown (e.g., by substantially simultaneous oxidation/nitridation of silicon or by oxidation of sputtered hafnium) or deposited (e.g., by chemical vapor deposition). The deposited gate oxide layer 20 may be thermally annealed following its deposition. In a further embodiment, gate oxide layer 20 may comprise a bilayer, such as an underlying silicon dioxide buffer layer with an overlying high k oxide thereon.

A metal nitride layer 30 and a polysilicon layer 40 are sequentially formed on the gate oxide layer 20. The metal nitride layer 30 may comprise metal nitrides that adhere to the underlying gate oxide layer 20 under typical processing conditions and provide a gate electrode work function sufficient to minimize or reduce any depletion layer in the underlying channel. For example, the metal nitride layer 30 of the formula MNₓ, where x is at least 1 and is generally about 2, and M is a refractory and/or transition metal capable of forming a conductive nitride. In various embodiments, M can be cobalt, nickel, tungsten, molybdenum, titanium, hafnium or tantalum, but those metals providing highly conductive nitrides (such as cobalt) are preferred. The metal nitride layer 30 generally has a thickness that can be easily dry etched by a reactive ion etching (RIE) process or the like. To this end, the metal nitride layer 30 may be ⅓ to ½ the thickness of the polysilicon layer 40. Alternatively or additionally, the metal nitride layer 30 may have a thickness ranging from approximately 20 nm to approximately 30 nm, and/or the polysilicon layer 40 may have a thickness ranging from 50 nm to approximately 100 nm.

Referring to FIG. 2, a photoresist (not shown) is coated on the polysilicon layer 40, and a photoresist pattern is projected onto the photoresist using an exposure apparatus such as a stepper. The projected photoresist pattern (not shown) is developed to form a photoresist pattern (not shown). Then, the polysilicon layer 40, the metal nitride layer 30, and the gate oxide layer 20 are sequentially dry etched to form a polysilicon layer pattern 41, a metal nitride layer pattern 31, and a gate oxide layer pattern 21, respectively. The dry etching operation may etch the polysilicon layer 40 and the metal nitride layer 30 at the same time, or may etch the polysilicon layer 40 and the metal nitride layer 30 in sequence, depending on etching conditions.

Referring to FIG. 3, a lightly doped drain (LDD) 11 is formed in the semiconductor substrate 10 by implanting a low concentration of impurity ions into the exposed surface of the semiconductor substrate 10 using a known method. Then, spacers S are formed on the sides of the polysilicon pattern 41, the metal nitride layer pattern 31, and the gate oxide layer pattern 21. Spacers S generally comprise one or more layers dielectric materials, such as silicon dioxide, silicon nitride, silicon oxynitride, etc. In certain embodiments, spacers S comprise a bilayer (e.g., silicon nitride on silicon dioxide) or a trilayer (e.g., a silicon dioxide/silicon nitride/silicon dioxide stack) structure. Source/drain regions 12 are formed by implanting a high concentration of impurity ions (generally the same conductivity type as for the LDD regions 11) using the polysilicon layer pattern 41 and the spacers S as an ion implantation mask.

Referring to FIG. 4, a metal (e.g., cobalt, nickel, tungsten, molybdenum, titanium, hafnium or tantalum, but preferably cobalt (Co) or nickel (Ni)) layer 50 is deposited over the semiconductor substrate 10, and a primary rapid thermal processing (RTP) is performed to form a primary compound (e.g., CoSi) of silicon and the metal on the source/drain regions 12 and the polysilicon layer pattern 41. Thus, the metal 50 is generally one capable of forming a metal silicide compound under conventional annealing conditions for metal silicide formation. In one embodiment, the metal 50 is the same as the metal of the metal nitride layer 30. The remaining metal layer 50 is removed, and a secondary RTP is performed to form a slightly different metal silicide, that is, a second compound (CoSi₂) of silicon and metal, on the source/drain regions 12 and the polysilicon layer pattern 41 (see FIG. 5). Thus, the deposited metal 50 should have a thickness providing a sufficient amount of metal atoms to form the second metal silicide compound. Furthermore, the relative thicknesses of metal layer 50 to polysilicon layer 40 should be sufficient to convert substantially all of polysilicon layer pattern 41 and the metal layer 50 thereover to the second metal silicide compound.

Referring to FIG. 5, a channel remains in the semiconductor substrate 10 between the source/drain regions 12, and a gate oxide layer pattern 21 is over the channel. A metal nitride layer pattern 31 is on the gate oxide layer pattern 21, and a fully silicided poly-Si (FUSI) 60 is on the metal nitride layer pattern 31. The fully silicided poly-Si 60 will be referred to as silicide. The metal nitride layer pattern 31 may have a thickness that is ¼ to ½ (e.g., ⅓ to ½) the thickness of the silicide 60. The metal nitride layer pattern 31 may have a thickness ranging from approximately 20 nm to approximately 30 nm, and the silicide 60 may have a thickness ranging from 50 nm to approximately 100 nm.

Spacers S are on (opposed) sides of the gate oxide layer pattern 21, the metal nitride layer pattern 31, and the silicide 60.

A gate electrode including a metal nitride layer pattern and a silicide is on the gate oxide layer pattern 21. Therefore, compared with the related gate electrode formed of polysilicon, the probability that a depletion layer will be formed in the gate electrode decreases, thereby reducing or preventing malfunction of the semiconductor device.

Further, the metal nitride layer preferably has a thickness so that it can be dry etched, and the polysilicon layer is formed on the metal layer. The polysilicon layer and the metal nitride layer may be etched at the same time (e.g., sequentially, in situ and/or without breaking vacuum in the etching chamber). Therefore, compared with the related art, metal etching can be easily performed, and the potential misalignment in the replacement gate process can be avoided or prevented. In other words, while maintaining the gate-first process (e.g., first forming the gate electrode directly by photolithography), the probability that a depletion layer will be formed is reduced, and the potential misalignment issue can be avoided or prevented.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a semiconductor device, comprising:
forming a gate oxide layer, a metal nitride layer, and a polysilicon layer on a semiconductor substrate;
patterning the polysilicon layer, the metal nitride layer, and the gate oxide layer;
implanting ions into exposed regions of the semiconductor substrate;
depositing a metal layer on the semiconductor substrate and the patterned polysilicon layer, and performing a primary rapid thermal processing (RTP); and
removing remaining metal, and performing a second rapid thermal processing to form a metal silicide.

2. The method according to claim 1, wherein the metal nitride layer has a thickness that is ⅓ to ½ of a thickness of the polysilicon layer.

3. The method according to claim 1, wherein the metal layer has a thickness ranging from approximately 20 nm to approximately 30 nm.

4. The method according to claim 1, wherein the polysilicon layer has a thickness ranging from approximately 50 to approximately 100 nm.

5. The method according to claim 1, wherein forming a photoresist pattern on the polysilicon layer and sequentially etching the polysilicon layer, the metal nitride layer, and the gate oxide layer using the photoresist pattern as an etch mask.

6. The method according to claim 1, wherein the primary rapid thermal processing forms a first metal silicide compound and the second rapid thermal processing forms a second metal silicide compound different from the first metal silicide compound.

7. The method according to claim 6, wherein the metal layer has a thickness sufficient to provide an amount of metal atoms to form the second metal silicide compound.

8. The method according to claim 7, wherein the thicknesses of the metal layer and the polysilicon layer pattern are sufficient to convert substantially all of the polysilicon layer pattern and the metal layer to the second metal silicide compound.

9. The method according to claim 1, wherein the gate oxide layer comprises a high k oxide.

10. The method according to claim 1, wherein the metal nitride layer comprises a nitride of a first metal selected from the group consisting of cobalt, nickel, tungsten, molybdenum, titanium, hafnium and tantalum.

11. The method according to claim 1, wherein the metal silicide comprises a silicide of a second metal selected from the group consisting of cobalt, nickel, tungsten, molybdenum, titanium, hafnium and tantalum.

12. The method according to claim 9, wherein the first metal and the second metal comprise an identical metal.

13. The method according to claim 1, wherein implanting the ions into the exposed regions of the semiconductor substrate forms a lightly doped drain.

14. The method according to claim 13, further comprising forms a spacer on a side of the patterned polysilicon layer, patterned metal nitride layer, and patterned gate oxide layer, then implanting ions into newly exposed regions of the semiconductor substrate to form source/drain terminals.

15. A semiconductor device, comprising:
a semiconductor substrate including source/drain regions and a channel between the source/drain regions;
a gate oxide layer pattern on the channel;
a metal nitride layer pattern on the gate oxide layer pattern;
a silicide on the metal layer pattern; and
a spacer on sides of the gate oxide layer pattern, the metal nitride layer pattern, and the silicide,
wherein the metal nitride layer pattern has a thickness that is ¼ to ½ of a thickness of the silicide.

16. The semiconductor device according to claim 15, wherein the metal nitride layer pattern has a thickness ranging from approximately 20 to approximately 30 nm.

17. The semiconductor device according to claim 15, wherein the silicide has a thickness ranging from approximately 50 to approximately 100 nm.

18. The semiconductor device according to claim 16, wherein the wherein the gate oxide layer comprises a high k oxide.

19. The semiconductor device according to claim 15, wherein the metal nitride layer comprises a nitride of a first metal selected from the group consisting of cobalt, nickel, tungsten, molybdenum, titanium, hafnium and tantalum.

20. The semiconductor device according to claim 15, wherein the metal silicide comprises a silicide of a second metal selected from the group consisting of cobalt, nickel, tungsten, molybdenum, titanium, hafnium and tantalum.

21. The method according to claim 20, wherein the first metal and the second metal comprise an identical metal.
